(19) United States
(12) Patent Application Publication
(10) Pub. No.: US 2018/0013261 A1
(43) Pub. Date: Jan. 11, 2018

(54) OPTICAL ELEMENT AND LIGHT GENERATING DEVICE

(71) Applicant: FUJITSU LIMITED, Kawasaki-shi (JP)

(72) Inventors: Takeshi Matsumoto, Ebina (JP); Suguru Akiyama, Tsukuba (JP); Manabu Matsuda, Atsugi (JP)

(73) Assignee: FUJITSU LIMITED, Kawasaki-shi (JP)

(21) Appl. No.: 15/626,572

(22) Filed: Jun. 19, 2017

(30) Foreign Application Priority Data
Jul. 5, 2016 (JP) 2016-133315

(51) Int. Cl. H01S 5/026; H01S 5/06; H01S 5/068

(52) U.S. Cl. CPC H01S 5/026; H01S 5/06821; H01S 5/0612; H01S 5/068

(57) ABSTRACT

An optical element includes a first optical waveguide that extends from a first end portion toward a second end portion, and has a first active layer, a second optical waveguide that has a second active layer, and is disposed side by side with the first optical waveguide and extends from the first end portion toward the second end portion, a reflective film disposed on an end face of the first optical waveguide at a side of the first end portion, and an anti-reflection film disposed on an end face of the second optical waveguide at the side of the first end portion, wherein the anti-reflection film extends from a side of the second optical waveguide to the first optical waveguide at the first end portion, and the reflective film includes the anti-reflection film as one of constituent elements.

### CROSS-REFERENCE TO RELATED APPLICATION

This application is based upon and claims the benefit of priority of the prior Japanese Patent Application No. 2016-133315, filed on Jul. 5, 2016, the entire contents of which are incorporated herein by reference.

### FIELD

The embodiments discussed herein are related to an optical element and a light generating device.

### BACKGROUND

Optical elements and light generating devices have conventionally been used in a wavelength division multiplexing (WDM) communication, a wavelength tunable laser, an optical transceiver, or the like.

There has been suggested a silicon photonics technology of manufacturing an optical element or a light generating device by combining a silicon wire waveguide formed by microfabrication of a silicon semiconductor manufacturing technology, with a light generator made of a compound semiconductor technology.

In the silicon photonics technology, studies have been made on a light generating device manufactured using a III-V group compound semiconductor having a high luminous efficiency such as an InP-based semiconductor instead of indirect transition-type silicon having a low luminous efficiency, as a light generator.

FIG. 1A is a plan view of a light generating device according to a conventional example, and FIG. 1B is a side view of the light generating device according to the conventional example.

A light generating device 130 is a wavelength tunable laser formed using a silicon photonics technology. The light generating device 130 includes a light generator 110a that generates light, an oscillator 141 that oscillates light having a selected wavelength from the light generated by the light generator 110a, and an optical amplifier 110b that amplifies the oscillated light. The light generator 110a and the optical amplifier 110b are made of a compound semiconductor. The oscillator 141 is formed using a silicon semiconductor manufacturing technology.

The light generator 110a includes an optical waveguide 111 including an active layer into which current is injected to generate light. An anti-reflection film 115a is disposed at an end portion of the light generator 110a at the oscillator 141 side. The end face of the light generator 110a at the optical amplifier 110b side is formed as a cleavage plane.

The optical amplifier 110b includes an optical waveguide 112 including an active layer into which current is injected to amplify the intensity of input light. Anti-reflection films 113 and 115b are disposed at both ends of the optical waveguide 112.

The oscillator 141 includes an optical waveguide made of silicon, two ring resonators that select a wavelength to be oscillated, a loop mirror that reflects light propagating through the optical waveguide, and the like. The oscillator 141 reflects light propagating through the optical waveguide between the end face of the light generator 110a at the optical amplifier 110b side and the loop mirror, and oscillates the light of the selected wavelength. A part of the oscillated light is output from the end face of the light generator 110a at the optical amplifier 110b side, amplified by the optical amplifier 110b, and output to the outside.

The light generator 110a, the optical amplifier 110b, and the oscillator 141 are disposed on a silicon substrate 140.

The oscillator 141 is formed by processing, for example, an SOT wafer having a single crystal silicon layer, a silicon oxide layer, and a silicon substrate, using the silicon semiconductor manufacturing technology.

The light generator 110a and the optical amplifier 110b are formed separately from the oscillator 141, and disposed on the substrate 140 from which a single crystal silicon layer and a silicon oxide layer are removed. The light generator 110a is bonded to the substrate 140 using a bonding portion 142a. The optical amplifier 110b is bonded to the substrate 140 using a bonding portion 142b.

The optical waveguide 111 of the light generator 110a is optically coupled with the optical waveguide of the oscillator 141 through a butt coupling. The optical waveguide 111 of the light generator 110a is optically coupled with the optical waveguide 112 of the optical amplifier 110b through a butt coupling.

The oscillator 141 oscillates light having a selected wavelength in cooperation with the light generator 110a. However, when the intensity of propagating light is large, the operation of an optical waveguide made of silicon may become unstable due to a nonlinear effect of light. Thus, the light generator 110a is driven under such a condition that the operation of the oscillator 141 does not become unstable.

Accordingly, the light output from the light generator 110a is amplified to a sufficient light intensity using the optical amplifier 110b and output to the outside.

The manufacturing of the above described light generating device 130 involves two manufacturing steps of bonding two components to the substrate 140 because each of the light generator 110a and the optical amplifier 110b formed separately from the oscillator 141 is bonded to the substrate 140.

Meanwhile, from the viewpoint of manufacturing a light generating device, the configuration may be simple. For example, the number of components and the number of manufacturing steps may be reduced.

The followings are reference documents.
[Document 1] Japanese Laid-Open Patent Publication No. 2012-256946, and
[Document 2] K. Sato et al., “High Output Power and Narrow Linewidth Silicon Photonic Hybrid Ring-Filter External Cavity Wavelength Tunable Lasers”, European Conference on Optical Communication (ECOC), Presentation Number PD.2.3, 2014.

### SUMMARY

According to an aspect of the invention, an optical element includes a first optical waveguide that extends from a first end portion toward a second end portion, and has a first active layer, a second optical waveguide that has a second active layer, and is disposed side by side with the first optical waveguide and extends from the first end portion toward the second end portion, a reflective film disposed on an end face of the first optical waveguide at a side of the first end portion, and an anti-reflection film disposed on an end face of the second optical waveguide at the side of the first end portion, wherein the anti-reflection film extends from a side of the second optical waveguide to the first optical waveguide at the first end portion, and the reflective film includes the anti-reflection film as one of constituent elements.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a plan view of a light generating device according to a conventional example, and FIG. 1B is a side view of the light generating device according to the conventional example;

FIG. 2 is a view illustrating an optical element according to a first embodiment of the present disclosure in the specification;

FIG. 3 is a sectional view taken along the X-X line of FIG. 2 in an enlarged scale;

FIG. 4 is a view illustrating the relationship between a reflectance and a wavelength of an anti-reflection film and a reflective film;

FIG. 5 is a view illustrating an optical element according to a second embodiment of the present disclosure in the specification;

FIG. 6 is a view illustrating an optical element according to a third embodiment of the present disclosure in the specification;

FIG. 7 is a plan view of a light generating device according to a first embodiment of the present disclosure in the specification;

FIG. 8 is a side view of the light generating device according to the first embodiment; and

FIG. 9 is a plan view illustrating a light generating device according to a second embodiment of the present disclosure in the specification.

### DESCRIPTION OF EMBODIMENTS

Hereinafter, detailed descriptions will be made on a first embodiment of an optical element disclosed in the present specification with reference to the accompanying drawings. Meanwhile, the technical scope of the present disclosure is not limited to the embodiment, but extends to the invention described in claims and equivalents thereof.

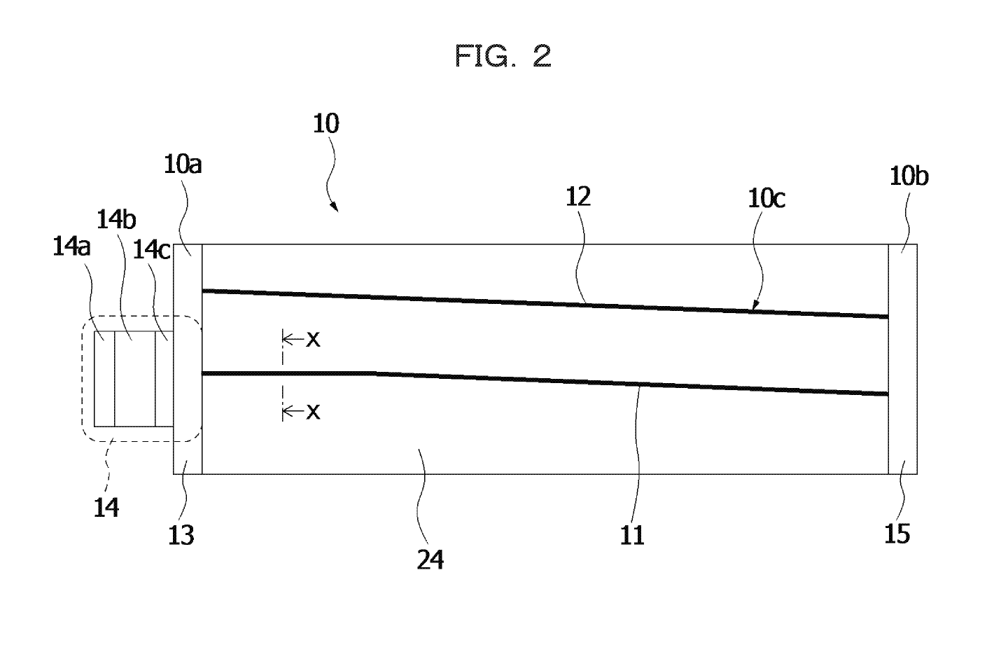

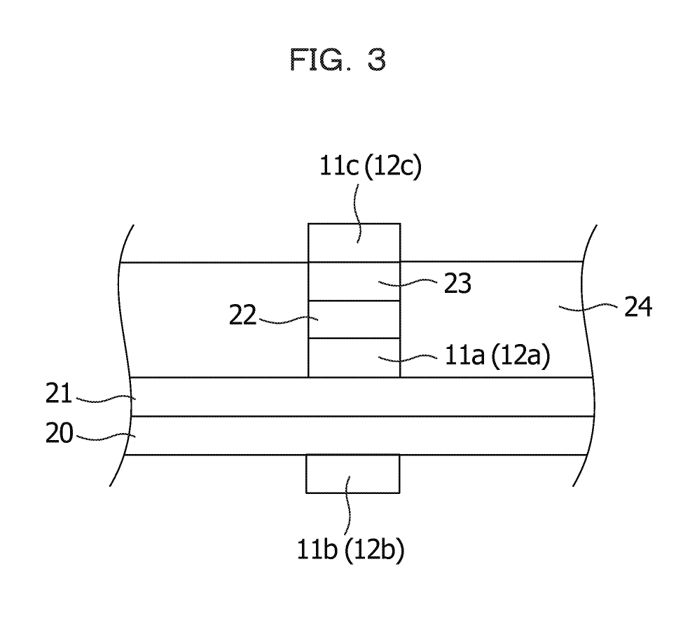

FIG. 2 is a view illustrating an optical element according to a first embodiment of the present disclosure in the specification. FIG. 3 is a sectional view taken along the X-X line of FIG. 2 in an enlarged scale.

The optical element 10 according to the present embodiment includes a first end portion 10a as one end portion in a direction where light propagates, and a second end portion 10b as the other end portion. The optical element 10 includes a first optical waveguide 11 that extends from the first end portion 10a toward the second end portion 10b and has a first active layer 11a. The optical element 10 includes a second optical waveguide 12 that has a second active layer 12a, and is disposed side by side with the first optical waveguide 11 and extends from the first end portion 10a toward the second end portion 10b.

As illustrated in FIG. 3, the first optical waveguide 11 includes a compound semiconductor substrate 20, a lower clad layer 21 disposed on the substrate 20, the first active layer 11a disposed on the lower clad layer 21, an upper clad layer 22 disposed on the first active layer 11a, and a contact layer 23 disposed on the upper clad layer 22. Each of the layers is also made of a compound semiconductor. The first active layer 11a, the upper clad layer 22, and the contact layer 23 form a mesa structure. Both sides of the mesa structure are buried by a buried layer 24. A lower electrode layer 11b is disposed at a portion of the outer surface of the substrate 20 corresponding to the mesa structure. An upper electrode layer 11c is disposed on the contact layer 23. In FIG. 2, a description of the upper electrode layer 11c is omitted. The substrate 20 and the lower clad layer 21 extend from the first optical waveguide 11 to the second optical waveguide 12.

The second optical waveguide 12 has the same structure as the first optical waveguide 11. The second optical waveguide 12 includes a compound semiconductor substrate 20, a lower clad layer 21 disposed on the substrate 20, the second active layer 12a disposed on the lower clad layer 21, an upper clad layer 22 disposed on the second active layer 12a, and a contact layer 23 disposed on the upper clad layer 22 as illustrated in FIG. 3. Each of the layers is also made of a compound semiconductor. The second active layer 12a, the upper clad layer 22, and the contact layer 23 form a mesa structure. A lower electrode layer 12b is disposed at a portion of the outer surface of the substrate 20 corresponding to the mesa structure. An upper electrode layer 12c is disposed on the contact layer 23. In FIG. 2, a description of the upper electrode layer 12c is omitted. The lower electrode layer 12b may be formed integrally with the lower electrode layer 11b.

The first optical waveguide 11 and the second optical waveguide 12 form an optical waveguide array 10c.

The first optical waveguide 11 is injected with current from the outside to generate light in the first active layer 11a.

The second optical waveguide 12 is injected with current from the outside to amplify the intensity of light propagating through the second active layer 12a.

The optical element 10 includes a reflective film 14 disposed on the end face of the first optical waveguide 11 at the first end portion 10a side. The reflective film 14 reflects light directed to the first end portion 10a through the first optical waveguide 11, toward the second end portion 10b side.

A portion of the first optical waveguide 11 at the first end portion 10a side extends vertically toward the reflective film 14, and is configured to increase the reflectance when light directed toward the first end portion 10a through the first optical waveguide 11 is reflected toward the second end portion 10b side.

The optical element 10 includes an anti-reflection film 13 disposed on the end face of the second optical waveguide 12 at the first end portion 10a side. Light propagating through the second optical waveguide 12 from the second end portion 10b side toward the first end portion 10a is output to the outside through the anti-reflection film 13.

The second optical waveguide 12 extends obliquely, rather than vertically, toward the anti-reflection film 13, and is configured to reduce the reflectance when light directed toward the first end portion 10a through the second optical waveguide 12 is reflected toward the second end portion 10b side.

The anti-reflection film 13 extends from the second optical waveguide 12 side to the first optical waveguide 11 at the first end portion 10a of the optical element 10, and covers the end face of the first optical waveguide 11. The reflective film 14 includes the anti-reflection film 13 as one of constituent elements of the reflective film 14.

As described above, the anti-reflection film 13 is disposed to cover the end face of the first optical waveguide 11 at the first end portion 10a side and the end face of the second optical waveguide 12 at the first end portion 10a side. Meanwhile, the reflective film 14 covers the end face of the first optical waveguide 11 at the first end portion 10a side, but does not cover the end face of the second optical waveguide 12 at the first end portion 10a side.

On the second end portion 10b in the first optical waveguide 11, an anti-reflection film 15 is disposed to cover the end face of the first optical waveguide 11 at the second end portion 10b side and the end face of the second optical waveguide 12 at the second end portion 10b side.

The light propagating through the first optical waveguide 11 from the first end portion 10a side toward the second end portion 10b is output to the outside through the anti-reflection film 15. The light propagating from the outside toward the end face of the second optical waveguide 12 at the second end portion 10b side is input to the second optical waveguide 12 through the anti-reflection film 15.

The reflectance of the anti-reflection film 13 and the anti-reflection film 15 may be 0.1% or less, may be 0.05% or less, and may be 0.005% or less.

The reflectance of the reflective film 14 may be 70% or more, may be 80% or more, and may be 90% or more.

The anti-reflection film 13 and the anti-reflection film 15 may be made of, for example, a dielectric material. For example, the anti-reflection film 13 and the anti-reflection film 15 may be formed using Si₃N₄, or a lamination of MgF₂ and TiO₂. In the present embodiment, the anti-reflection film 13 and the anti-reflection film 15 are formed using Si₃N₄ with a thickness of 218 nm.

The reflective film 14 may be formed using a dielectric material or a lamination of a dielectric material and a metal film. The reflective film 14 of the present embodiment is formed by laminating a plurality of dielectric films. Specifically, the reflective film 14 is formed by laminating a Si₃N₄ film (anti-reflection film 13) with a thickness of 218 nm, an amorphous silicon film 14a with a thickness of 110 nm, and a silicon oxide film 14b with a thickness of 268 nm, and an amorphous silicon film 14c with a thickness of 110 nm.

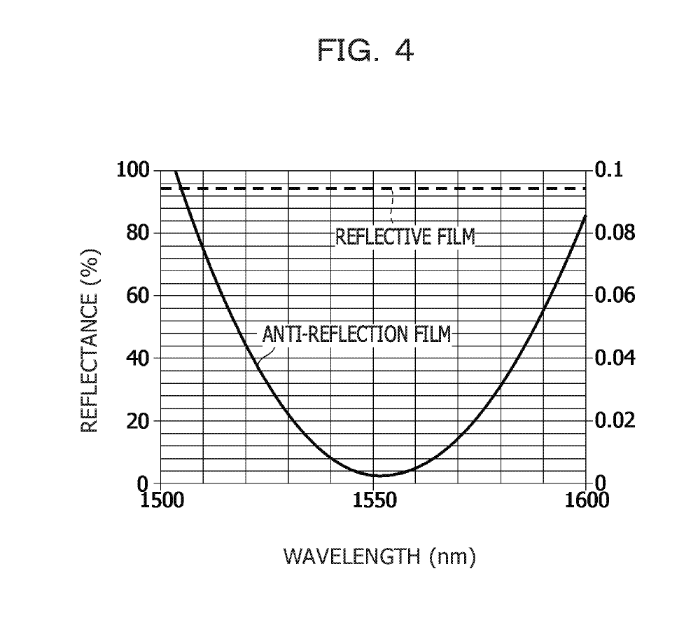

FIG. 4 is a view illustrating the relationship between a reflectance and a wavelength of an anti-reflection film and a reflective film in the optical element of the present embodiment.

The anti-reflection film 13 has a reflectance of about 0.003% at a wavelength of 1550 nm, and the reflective film 14 has a reflectance of about 94% at a wavelength of 1550 nm.

The reflective film 14 includes the anti-reflection film 13 having a reflectance of about 0.003% at a wavelength of 1550 nm, as a constituent element. However, as illustrated in FIG. 4, it can be found that out the reflective film 14 exhibits a high reflectance in a wide wavelength range, and has a sufficient function of reflecting light.

When the optical element 10 is manufactured, the anti-reflection film 13 may be formed on the end face of the cleaved first end portion 10a using a conventionally known film forming technology. The anti-reflection film 13 may be formed over the entire end face of the cleaved first end portion 10a in view of protecting the end face of the first end portion 10a. The reflective film 14 may be formed by forming another film on the anti-reflection film 13 using a conventionally known film forming technology.

In general, the accuracy of the film thickness of the anti-reflection film 13 is required to be higher than that of the reflective film 14. Thus, as described above, the anti-reflection film 13 is formed first on the end face of the first end portion 10a, and the reflective film 14 is formed on the anti-reflection film 13 in view of obtaining the anti-reflection film 13 having a high optical characteristic.

The above described optical element 10 according to the present embodiment may include a function of generating light and a function of amplifying light in one element.

The forming material, the film thickness, or the structure of the above described anti-reflection film 13 is exemplary only. As long as the anti-reflection film 13 has an anti-reflection function, the forming material, the film thickness, or the structure of the anti-reflection film 13 may be properly set.

The forming material, the film thickness, or the structure of the above described reflective film 14 is exemplary only. As long as the reflective film 14 has a reflection function, the forming material, the film thickness, or the structure of the reflective film 14 may be properly set.

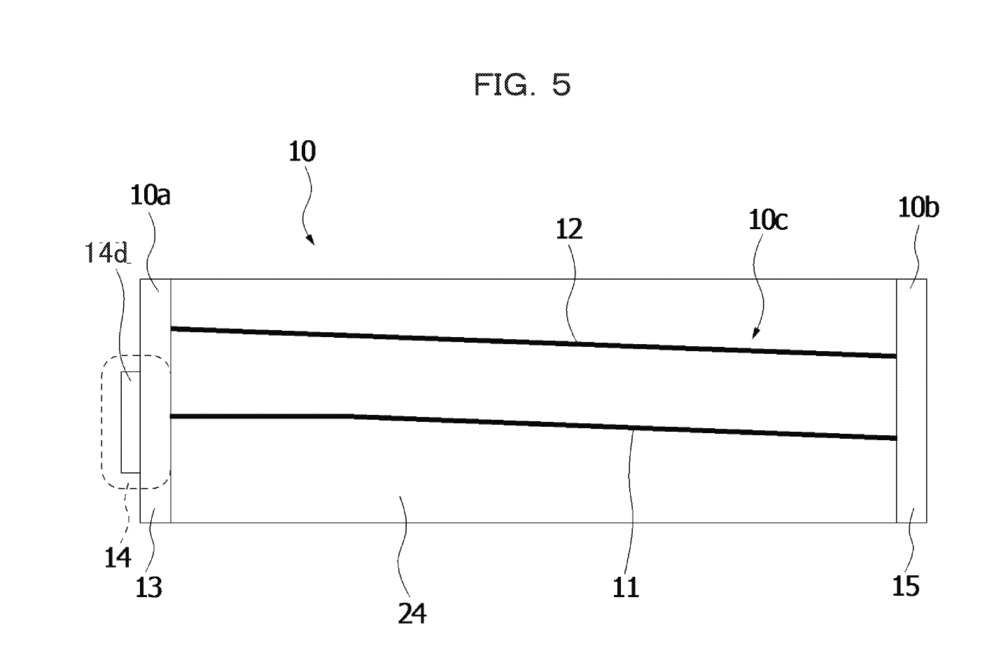

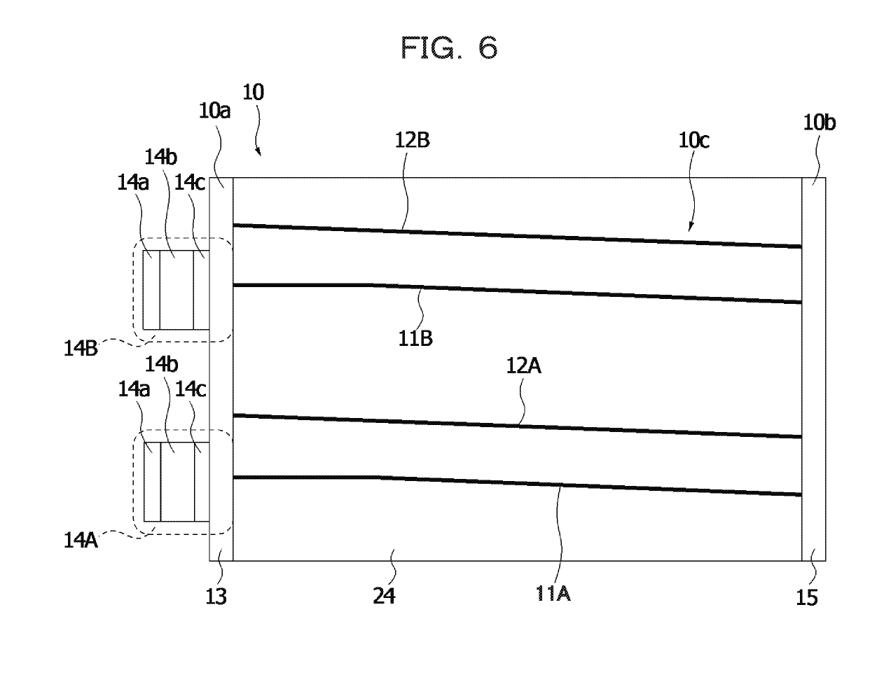

Next, another embodiment of the above described optical element will be described with reference to FIGS. 5 and 6. For the points of another embodiment that are not specifically described, the above description for the above described first embodiment is properly applied. The same constituent elements are denoted by the same reference numerals.

FIG. 5 is a view illustrating an optical element according to a second embodiment of the present disclosure in the specification.

In the optical element 10 of the present embodiment, the reflective film 14 includes an anti-reflection film 13, and a metal film 14d disposed on the anti-reflection film 13. The reflective film 14 may achieve a high reflectance particularly in an infrared wavelength region by including the metal film 14d.

As a material for forming the metal film 14d, for example, aluminum, gold, or the like may be used.

In order to suppress oxidation of the surface of the metal film 14d, a protective film for suppressing oxidation may be formed on the surface of the metal film 14d.

In order to improve the adhesion between the metal film 14d and the anti-reflection film 13, a base film such as a Cr film may be disposed between the metal film 14d and the anti-reflection film 13.

According to the above described optical element 10 of the present embodiment, the reflectance of the reflective film 14 in the infrared wavelength region may be improved.

FIG. 6 is a view illustrating an optical element according to a third embodiment of the present disclosure in the specification.

The optical element 10 of the present embodiment includes two first optical waveguides 11A and 11B, and two second optical waveguides 12A and 12B.

The optical waveguide array 10c is formed by the two first optical waveguides 11A and 11B, and the two second optical waveguides 12A and 12B.

The first optical waveguide 11A is disposed next to the second optical waveguide 12A, and the first optical waveguide 11B is disposed next to the second optical waveguide 12B.

Each of the first optical waveguide 11A and the first optical waveguide 11B is injected with current from the outside to generate light in the active layer.

Each of the second optical waveguide 12A and the second optical waveguide 12B is injected with current from the outside to amplify the intensity of light propagating through the active layer.

The optical element 10 includes an anti-reflection film 13 disposed on a first end portion 10a. The anti-reflection film 13 has the same structure as the anti-reflection film disposed on the first end portion of the optical element according to the first embodiment as described above. The optical element 10 includes an anti-reflection film 15 disposed on a second end portion 10b. The anti-reflection film 15 has the same structure as the anti-reflection film disposed on the second end portion of the optical element according to the first embodiment as described above.

The anti-reflection film 13 covers end faces of the first optical waveguide 11A and the first optical waveguide 11B, and the second optical waveguide 12A and the second optical waveguide 12B at the first end portion 10a side.

Similarly, the anti-reflection film 15 covers the end faces of the first optical waveguide 11A and the first optical waveguide 11B, and the second optical waveguide 12A and the second optical waveguide 12B at the second end portion 10b side.

The optical element 10 includes a reflective film 14A disposed on the end face of the first optical waveguide 11A at the first end portion 10a side. The optical element 10 includes a reflective film 14B disposed on the end face of the first optical waveguide 11B at the first end portion 10a side.

The reflective film 14A and the reflective film 14B include the anti-reflection film 13 as one of constituent elements of the reflective film 14. Each of the reflective film 14A and the reflective film 14B has the same structure as the above described reflective film according to the first embodiment.

The reflective film 14A covers the end face of the first optical waveguide 11A at the first end portion 10a side, but does not cover the end face of the second optical waveguide 12A at the first end portion 10a side. Similarly, the reflective film 14B covers the end face of the first optical waveguide 11B at the first end portion 10a side, but does not cover the end face of the second optical waveguide 12B at the first end portion 10a side.

The optical element 10 according to the present embodiment includes two optical elements according to the first embodiment as described above, in one element. Thus, the size of a region where the optical element is disposed may be made smaller than in the case where two optical elements according to the first embodiment are separately disposed.

The optical element 10 according to the present embodiment includes two first optical waveguides, but may include three or more first optical waveguides. The optical element 10 according to the present embodiment includes two second optical waveguides, but may include three or more second optical waveguides. The number of first optical waveguides included in the optical element may be the same as or different from the number of second optical waveguides.

Next, a first embodiment of a light generating device including the above described optical element disclosed in the specification will be described with reference to accompanying drawings.

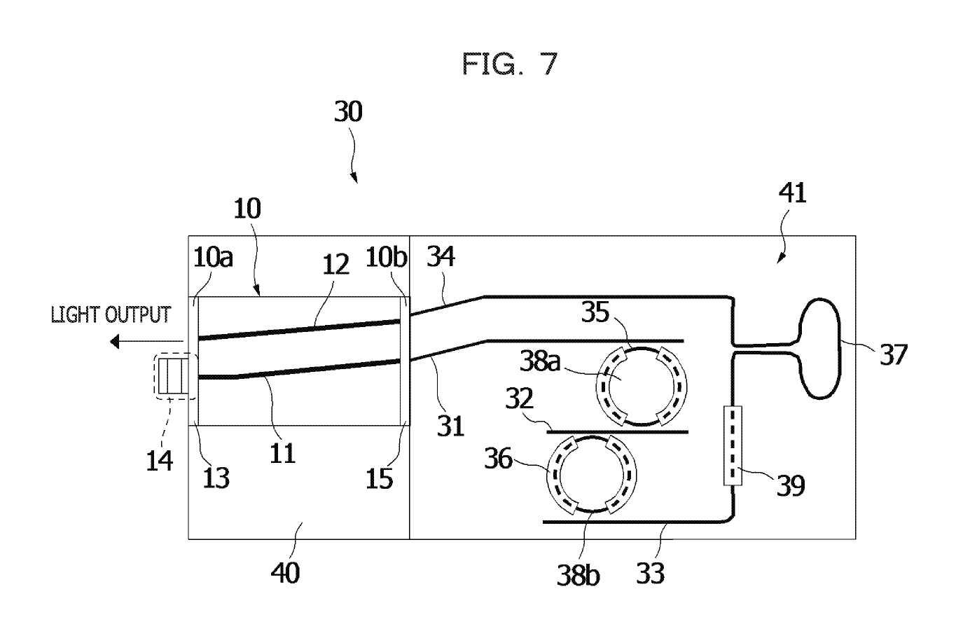

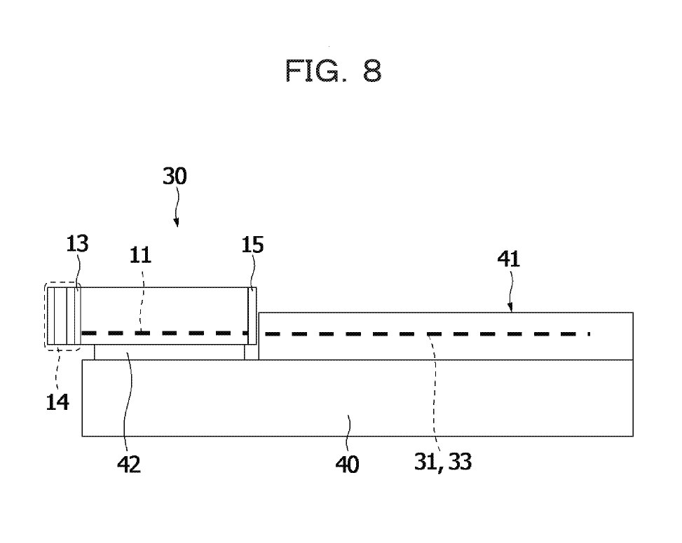

FIG. 7 is a plan view of a light generating device according to a first embodiment of the present disclosure in the specification. FIG. 8 is a side view of the light generating device according to the first embodiment as illustrated in FIG. 7.

A light generating device 30 according to the present embodiment is a wavelength tunable laser device of which the oscillating wavelength of a laser is variable.

The light generating device 30 includes the above described optical element 10 according to the first embodiment, and an oscillator 41 that oscillates light having a selected wavelength from the light generated by the optical element 10. The optical element 10 and the oscillator 41 are disposed on the same silicon substrate 40. Each of constituent elements of the light generating device 30 is controlled by a controller (not illustrated).

The oscillator 41 is formed by processing, for example, an SOI wafer having a single crystal silicon layer, a silicon oxide layer, and a silicon substrate, using a silicon semiconductor manufacturing technology.

The optical element 10 is disposed on the substrate 40 from which a single crystal silicon layer and a silicon oxide layer are removed. The optical element 10 is bonded to the substrate 40 using a bonding portion 42. As the bonding portion 42, an AuSn solder may be used. A lower electrode made of Au is disposed in a region of the optical element 10 to be bonded to the bonding portion 42. The optical element 10 is bonded to the substrate 40 by flip-chip bonding with each bonding portion 42 facing the lower electrode.

As illustrated in FIG. 7, the oscillator 41 includes optical elements such as four optical waveguides 31, 32, 33, and 34, a first ring resonator 35, a second ring resonator 36, and a partial reflection mirror 37.

Respective optical elements are integrated on the silicon substrate 40 using a silicon semiconductor manufacturing technology. As the four optical waveguides 31, 32, 33, and 34, the first ring resonator 35, the second ring resonator 36, and the partial reflection mirror 37, silicon wire optical waveguides in which a silicon single crystal layer is processed may be used. On the silicon wire optical waveguides, a clad layer (see, e.g., FIG. 8) is disposed. In FIG. 7, description of the clad layer is omitted.

The optical waveguide 31 is optically coupled with the first optical waveguide 11 of the optical element 10, on the end face of the first optical waveguide 11 at the second end portion 10b side, and propagates light generated by the first optical waveguide 11 therethrough. The first optical waveguide 11 is optically coupled with the optical waveguide 31 through a butt coupling.

The optical waveguide 34 is optically coupled with the second optical waveguide 12, on the end face of the second optical waveguide 12 at the second end portion 10b side. The second optical waveguide 12 is optically coupled with the optical waveguide 34 through a butt coupling.

The first ring resonator 35 is disposed between the optical waveguide 31 and the optical waveguide 32. The optical waveguide 31 and the optical waveguide 32 are optically coupled with the first ring resonator 35. The second ring resonator 36 is disposed between the optical waveguide 32 and the optical waveguide 33. The optical waveguide 32 and the optical waveguide 33 are optically coupled with the second ring resonator 36.

In the first ring resonator 35, the transmittance of light transmitting through the first ring resonator 35 is periodically changed with a wavelength. Similarly, in the second ring resonator 36 as well, the transmittance of light transmitting through the second ring resonator 36 is periodically changed with a wavelength. The transmission characteristics of the light transmitting through the first ring resonator 35 and the second ring resonator 36 are determined depending on the radius of curvature, the refractive index or the like. The radius of curvature of the first ring resonator 35 may be different from that of the second ring resonator 36 in view of accurately controlling an oscillating wavelength using a Vernier effect.

A heater 38a is disposed on the first ring resonator 35, which changes a temperature of the first ring resonator 35 and changes a refractive index, thereby changing the transmission characteristics of light. Similarly, a heater 38b is disposed on the second ring resonator 36, which changes a temperature of the second ring resonator 36 and changes a refractive index, thereby controlling the transmission characteristics of light.

In the light generating device 30, the first ring resonator 35 and the second ring resonator 36 function as a wavelength selector that selects a wavelength of light to be oscillated in the optical waveguide 31.

The optical waveguide 33 is optically coupled with the partial reflection mirror 37. The light generated by the first optical waveguide 11 of the optical element 10 is reflected between the partial reflection mirror 37 and the reflective film 14 disposed on the first end portion 10a of the optical element 10, and thus light with a wavelength selected by a wavelength selector oscillates in an optical path including the optical waveguide 31. In the light generating device 30, the partial reflection mirror 37 and the reflective film 14 function as an oscillator that oscillates light with a wavelength selected by the wavelength selector in the optical path including the optical waveguide 31.

A phase adjuster 39 is disposed on a portion of the optical waveguide 33 at the partial reflection mirror 37 side. The phase adjuster 39 changes the temperature of the optical waveguide 33, and thus changes the refractive index, thereby controlling the phase of propagating light. The phase adjuster 39, together with the first ring resonator 35 and the second ring resonator 36, is used to control the wavelength of light oscillating within the optical waveguide 31.

The first optical waveguide 11 of the optical element 10 propagates generated light to the optical waveguide 31. The first optical waveguide 11 extends obliquely with respect to the end face at the second end portion 10b side by a predetermined angle from its normal line. The optical waveguide 31 also extends obliquely with respect to the end face at the second end portion 10b side by a predetermined angle from its normal line.

The light generated by the first optical waveguide 11 of the optical element 10 propagates through a path formed by the first optical waveguide 11 of the optical element 10, the optical waveguides 31, 32, and 33, the first ring resonator 35, and the second ring resonator 36. The light oscillating in the optical path including the optical waveguide 31 oscillates while being reflected between the reflective film 14 and the partial reflection mirror 37.

The optical path length including the optical waveguides 31, 32, and 33 and the first optical waveguide 11 may be properly determined according to a spectral width required for oscillating laser. In general, the longer the optical path length, the narrower the obtained spectral width.

The partial reflection mirror 37 reflects light propagating through the optical waveguide 33 toward the partial reflection mirror 37. When light propagates through the optical waveguide 33 toward the partial reflection mirror 37, the partial reflection mirror 37 propagates a part of the light to the optical waveguide 34 through the partial reflection mirror 37.

Here, the oscillator 41 oscillates light having a selected wavelength in cooperation with the first optical waveguide 11 of the optical element 10. However, when the intensity of propagating light is large, the operation of an optical waveguide made of silicon may become unstable due to a nonlinear effect of light. Thus, the first optical waveguide 11 is driven under such a condition that the operation of the oscillator 41 does not become unstable.

The optical waveguide 34 propagates light oscillating in the optical path including the optical waveguide 31, to the second optical waveguide 12 of the optical element 10.

The second optical waveguide 12 amplifies the intensity of light propagating through the second active layer 12a, while outputting the light from the end face at the first end portion 10a side to the outside through the anti-reflection film 13. The second active layer 12a amplifies the intensity of the light generated by the first optical waveguide 11 driven under a condition suitable for stable oscillation, to a desired magnitude.

According to the above described light generating device 30 of the present embodiment, since the optical element 10 in which a light generating function and a light amplifying function are incorporated in one element is provided, the number of components and the number of manufacturing steps may be reduced.

In relation to the light generating device 30 of the present embodiment, the improvement of bonding between the optical element 10 and the substrate 40 will be described below.

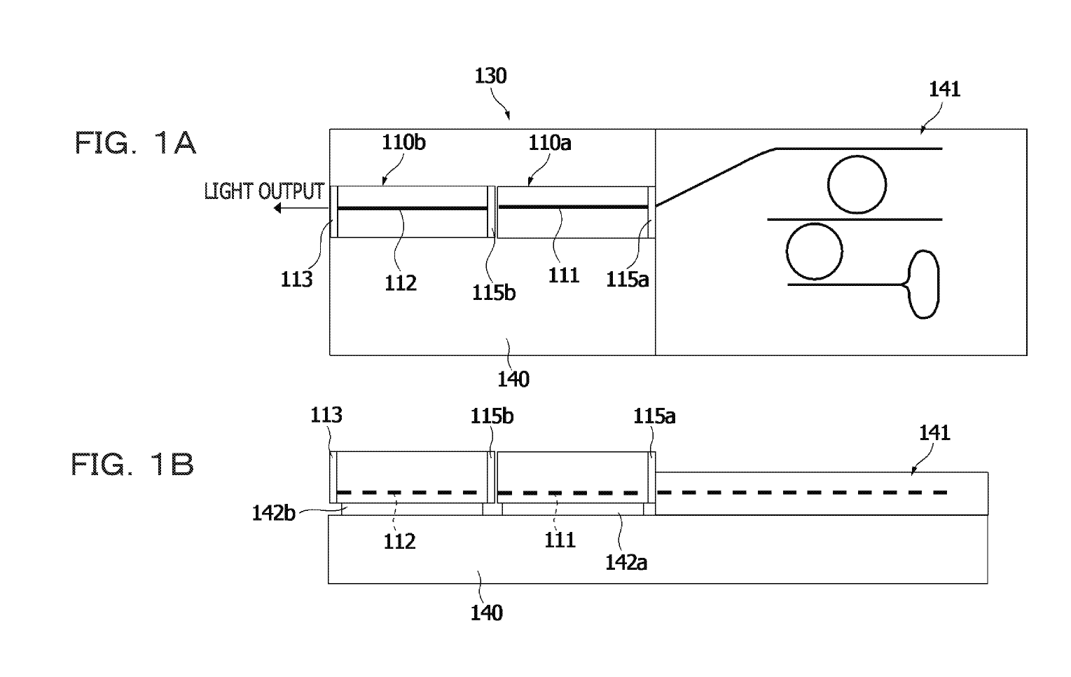

When the conventional light generating device illustrated in FIGS. 1A and 1B is manufactured, the light generator 110a is flip-chip bonded on the substrate 140, and then the optical amplifier 110b is flip-chip bonded on the substrate 140.

An AuSn solder that forms the bonding portion 142b on the substrate 140 to which the optical amplifier 110b is flip-chip bonded may be deteriorated by a thermal history when the light generator 110a is flip-chip bonded. Thus, there is a possibility that a defect may occur in the bonding between the optical amplifier 110b and the substrate 140.

Meanwhile, since the above described light generating device 30 of the present embodiment employs the optical element 10 in which a light generating function and a light amplifying function are incorporated in one element, the optical element 10 is bonded to the substrate 40 by performing flip-chip bonding once. Thus, a secure bonding may be obtained between the optical element 10 and the substrate 40.

In the light generating device 30 according to the embodiment as described above, the optical element 10 includes one first optical waveguide, but the optical element may include two or more first optical waveguides so as to generate a plurality of wavelength tunable lasers.

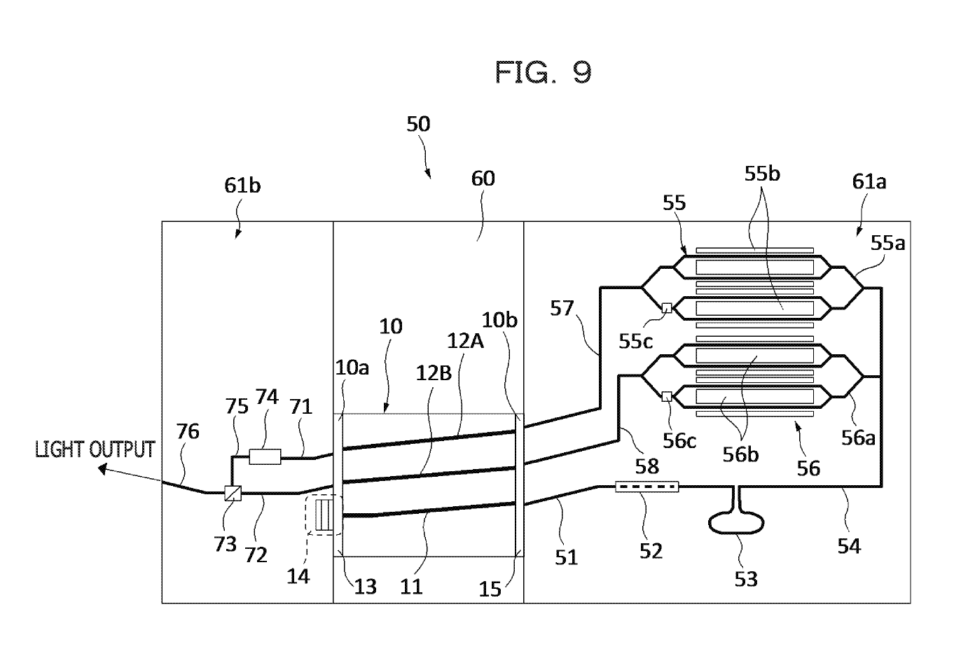

Hereinafter, a second embodiment of the light generating device as described above will be described with reference to FIG. 9. For the points of the second embodiment that are not specifically described, the above description for the above described first embodiment is properly applied. The same constituent elements are denoted by the same reference numerals.

FIG. 9 is a plan view illustrating a light generating device according to a second embodiment of the present disclosure in the specification.

A light generating device 50 of the present embodiment generates multi-level optical signals. Specifically, the light generating device 50 generates a quadrature phase shift keying (QPSK) signal or a quadrature amplitude modulation (QAM) signal.

The light generating device 50 includes an optical element 10, a modulator 61a, and an output unit 61b. The optical element 10, the modulator 61a, and the output unit 61b are disposed on the same silicon substrate 60. Each of constituent elements of the light generating device 50 is controlled by a controller (not illustrated).

Each of the modulator 61a and the output unit 61b is formed by processing, for example, an SOI wafer having a single crystal silicon layer, a silicon oxide layer, and a silicon substrate, using a silicon semiconductor manufacturing technology.

The optical element 10 is disposed on the substrate 60 from which a single crystal silicon layer and a silicon oxide layer are removed.

The optical element 10 includes a first optical waveguide 11, a second optical waveguide 12A, a second optical waveguide 12B, an anti-reflection film 13, a reflective film 14, and an anti-reflection film 15. The optical element 10 has the same structure as the optical element of the first embodiment as described above except that the optical element 10 has two second optical waveguides 12A and 12B. Each of the second optical waveguide 12A and the second optical waveguide 12B has the same structure as the second optical waveguide of the optical element of the first embodiment as described above.

The modulator 61a oscillates the light generated by the first optical waveguide 11 of the optical element 10, generates two modulated signals by performing quadrature phase shift modulation or quadrature amplitude modulation on the oscillated light, and outputs the generated signals to the optical element 10.

The modulator 61a includes an optical waveguide 51, a phase adjuster 52, a partial reflection mirror 53, an optical waveguide 54, a first IQ modulator 55, a second IQ modulator 56, an optical waveguide 57, and an optical waveguide 58.

The light generated by the first optical waveguide 11 is reflected between the reflective film 14 disposed on an end portion of the first optical waveguide 11 at the first end portion 10a side, and the partial reflection mirror 53, and oscillates at a predetermined wavelength in an optical path including the first optical waveguide 11. The phase adjuster 52 changes the temperature of the optical waveguide 51, and thus changes the refractive index, thereby controlling the phase of oscillating light.

When light propagates through the optical waveguide 51 toward the partial reflection mirror 53, the partial reflection mirror 53 propagates a part of the light to the optical waveguide 54 through the partial reflection mirror 53.

The light propagating through the optical waveguide 54 diverges to propagate through the first IQ modulator 55 and the second IQ modulator 56.

The first IQ modulator 55 has a structure where two Mach-Zehnder-type modulators are connected in parallel. The first IQ modulator 55 includes optical waveguides 55a, electrodes 55b, and a 90-degree phase shifter 55c which constitute two Mach-Zehnder-type modulators.

The light input from the optical waveguide 54 to the first IQ modulator 55 diverges to propagate through optical waveguides of the two Mach-Zehnder-type modulators. In the first IQ modulator 55, an electric field is applied to the optical waveguide 55a by the electrode 55b to which a voltage is applied by a controller (not illustrated) so that a phase of light propagating through the optical waveguide 55a is changed, and an optical signal in which the phase-changed light is combined and interferes with each other is generated. Then, one optical signal output from the Mach-Zehnder-type modulator, in which the phase is shifted by 90 degrees by the 90-degree phase shifter 55c, is combined with another optical signal that is not shifted so that a QPSK or QAM modulated optical signal is generated. The optical signal generated by the first IQ modulator 55 is output to the optical waveguide 57.

The second IQ modulator 56 has the same structure of the first IQ modulator 55. The second IQ modulator 56 includes optical waveguides 56a, electrodes 56b, and a 90-degree phase shifter 56c which constitute two Mach-Zehnder-type modulators.

The second IQ modulator 56 also generates a QPSK or QAM modulated optical signal by performing phase modulation or amplitude modulation on light input from the optical waveguide 54. The optical signal generated by the second IQ modulator 56 is output to the optical waveguide 58.

The optical signal propagating through the optical waveguide 57 is amplified by the second optical waveguide 12A of the optical element 10, and output to the output unit 61b. The optical signal propagating through the optical waveguide 58 is amplified by the second optical waveguide 12B of the optical element 10, and output to the output unit 61b.

The output unit 61b includes an optical waveguide 71, an optical waveguide 72, a polarization splitter/combiner 73, a polarization rotator device 74, an optical waveguide 75, and an optical waveguide 76.

The optical signal amplified by the second optical waveguide 12A of the optical element 10 is input to the optical waveguide 71 of the output unit 61b. The optical signal amplified by the second optical waveguide 12B of the optical element 10 is input to the optical waveguide 72 of the output unit 61b.

The optical signal propagating through the optical waveguide 71 is output to the optical waveguide 75 while the direction of polarization is rotated by the polarization rotator device 74. The optical signal propagating through the optical waveguide 75 has a different polarization direction from the optical signal propagating through the optical waveguide 72.

The optical signal propagating through the optical waveguide 75 is combined with the optical signal propagating through the optical waveguide 72 by the polarization splitter/combiner 73 and output to the optical waveguide 76. The light propagating through the optical waveguide 76 is output to the outside as a polarization-multiplexed QPSK or QAM signal. The polarization-multiplexed QPSK or QAM signal is used in, for example, a digital coherent communication.

In the present disclosure, the optical element and the light generating device according to embodiments as described above may be properly modified without departing from the gist of the present disclosure. Constituent features included in one embodiment may be properly applied to other embodiments.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. An optical element comprising:
a first optical waveguide that extends from a first end portion toward a second end portion, and has a first active layer;
a second optical waveguide that has a second active layer, and is disposed side by side with the first optical waveguide and extends from the first end portion toward the second end portion;
a reflective film disposed on an end face of the first optical waveguide at a side of the first end portion; and
an anti-reflection film disposed on an end face of the second optical waveguide at the side of the first end portion,
wherein the anti-reflection film extends from a side of the second optical waveguide to the first optical waveguide at the first end portion, and the reflective film includes the anti-reflection film as one of constituent elements.

2. The optical element according to claim 1, wherein the anti-reflection film is made of a dielectric material, and
the reflective film is formed by laminating the anti-reflection film, and another dielectric material different from the dielectric material or a metal film.

3. The optical element according to claim 1, wherein a plurality of first optical waveguides is provided.

4. The optical element according to claim 1, wherein a plurality of second optical waveguides is provided.

5. A light generating device comprising:
an optical element including
a first optical waveguide that extends from a first end portion toward a second end portion, and has a first active layer,
a second optical waveguide that has a second active layer, and is disposed side by side with the first optical waveguide and extends from the first end portion toward the second end portion,
a reflective film disposed on an end face of the first optical waveguide at a side of the first end portion, and
an anti-reflection film disposed on an end face of the second optical waveguide at the side of the first end portion,
wherein the anti-reflection film extends from a side of the second optical waveguide to the first optical waveguide at the first end portion, and the reflective film includes:
an optical device including the anti-reflection film as one of constituent elements;
a third optical waveguide optically coupled with the first optical waveguide on an end face of the first optical waveguide at a side of the second end portion, and that propagates light generated by the first optical waveguide; and
a fourth optical waveguide optically coupled with the second optical waveguide on an end face of the second optical waveguide at the side of the second end portion.

6. The light generating device according to claim 5, further comprising:
a wavelength selector that selects a wavelength of light to be oscillated in the third optical waveguide; and
an oscillator that oscillates the light with the wavelength selected by the wavelength selector in the third optical waveguide,
wherein the fourth optical waveguide propagates the light oscillating in the third optical waveguide to the second optical waveguide.

7. The light generating device according to claim 6, wherein the optical element, the third optical waveguide, the wavelength selector, the oscillator, and the fourth optical waveguide are disposed on a same substrate.
